(19) United States
(12) Patent Application Publication
(10) Pub. No.: US 2010/0056095 A1
(43) Pub. Date: Mar. 4, 2010

(54) DYNAMIC CURRENT INJECTION MIXER/MODULATOR

(75) Inventor: Chia-Hsin WU, Taipei County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK INC., Hsin-Chu (TW)

(21) Appl. No.: 12/202,612

(22) Filed: Sep. 2, 2008

(51) Int. Cl. H03D 7/14

(52) U.S. Cl. 455/333; 331/42

(57) ABSTRACT

A mixer is provided. The mixer comprises a Gilbert cell mixer core, a pair of load devices, a transconductor cell, and a current injection branch. The Gilbert cell mixer core has first and second nodes, receives a first differential input signal, and provides a differential output signal at the first nodes. The load devices are respectively coupled between the first nodes of the Gilbert cell mixer core and a first fixed voltage. The transconductor cell is coupled between the second nodes and a second fixed voltage and receives a second differential input signal. The dynamic current injection branch comprises first and second pairs of MOS transistors each connected in parallel and having drains commonly coupled to a corresponding second node and gates receiving a third differential input signal. There is a phase difference of 90° between the first and third differential input signals.

### BACKGROUND OF THE INVENTION

1. Field of the Invention

The invention relates to a double-balanced mixer and, in particular, to a double-balance mixer with a dynamic current injection branch.

2. Description of the Related Art

Mixer circuits for high frequency applications constructed using metal oxide semiconductor (MOS) transistors are subject to a limited voltage supply (usually less than 2V) and high levels of flicker noise, having frequencies extending to several tens of MHz. Accordingly, the gain and output signal level required in such mixer circuits exceed those required in equivalent bipolar circuits.

FIG. 1 is a circuit diagram illustrating a conventional double balanced mixer circuit. The double balanced mixer circuit in FIG. 1 includes differential pairs of MOSFETs (Q131-Q132 and Q133-Q134). The drains of the pairs of MOSFETs are connected to an output terminal (Output-I⁺ and Output-I⁻). The gates of the pairs of MOSFETs are connected to first input terminals (Input-II⁺ and Input-II⁻). The double balanced mixer circuit in FIG. 1 also includes active devices Q135, Q136, Q137 and Q138. The sources of the MOSFET pair Q131-Q132 are connected to the drains of the active devices Q135 and Q136. The sources of the MOSFET pair Q133-Q134 are connected to the drains of the active devices Q137 and Q138. The gates of the active devices Q135, Q136, Q137 and Q138 are connected to the second input terminal (Input-I⁺ and Input-I⁻). The sources of the active devices Q135, Q136, Q137 and Q138 are connected to the ground through an impedance unit (Degeneration Impedance).

FIG. 2 is a conventional mixer with a dynamic current injection mechanism disclosed in US patent application publication 2005/0164671 A1. The mixer includes first and second transconductance modules that includes MOSFETs configured to receive a plurality of signals that are to be mixed and a selectively coupled auxiliary current source to inject an auxiliary current into the second transconductance module approximately at or near a zero-crossing point in order to reduce flicker noise and other noise introduced into an output signal during switching. Accordingly, as a first transconductance module approaches a zero-crossing, auxiliary current is injected to reduce the current produced therefrom thereby reducing flicker noise. In a differential mixer, the amount of current produced from a transistor pair to which the signal cycle is being switched is also reduced thereby reducing noise from the transistor pair that is turning on for the next portion of a signal cycle.

### BRIEF SUMMARY OF THE INVENTION

An embodiment of a mixer comprises a Gilbert cell mixer core, a pair of load devices, a transconductor cell, and a current injection branch. The Gilbert cell mixer core has first and second nodes, receives a first differential input signal, and provides a differential output signal at the first nodes. The load devices are respectively coupled between the first nodes of the Gilbert cell mixer core and a first fixed voltage. The transconductor cell is coupled between the second nodes and a second fixed voltage and receives a second differential input signal. The dynamic current injection branch is coupled between a third fixed voltage and the second nodes. The dynamic current injection branch comprises first and second pairs of MOS transistors each connected in parallel and having drains commonly coupled to a corresponding second node and gates receiving a third differential input signal. There is a phase difference of 90° between the first and third differential input signals.

An embodiment of a quadrature mixer comprises first and second mixers connected in parallel between first and second fixed voltages. Each of the first and second mixers comprises a Gilbert cell mixer core, a pair of load devices, a dynamic current steering cell, and a transconductor cell. The Gilbert cell mixer core has first and second nodes, receives a first differential input signal, and provides a differential output signal at the first nodes. The load devices are respectively coupled between the first nodes of the Gilbert cell mixer core and a first fixed voltage. The transconductor cell is coupled between the second nodes and a second fixed voltage and receives a second differential input signal. The dynamic current injection branch is coupled between a third fixed voltage and the second nodes. The dynamic current injection branch comprises first and second pairs of MOS transistors each connected in parallel and having drains commonly coupled to a corresponding second node and gates receiving a third differential input signal. There is a phase difference of 90° between the first and third differential input signals. In addition, there is a phase difference of 90° between the first differential input signals of the first and second dynamic current injection mixers.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a circuit diagram illustrating a conventional double balanced mixer circuit;

FIG. 2 is a circuit diagram of a conventional quadrature mixer disclosed by Raja S Pullela et. al in ISSCC 2006;

FIG. 3A is a circuit diagram of a dynamic current injection mixer according to an embodiment of the invention;

FIG. 3B is a timing diagram showing waveforms of the local oscillator signal LO_I/LO_IB and differential input signal LO_Q and LO_QB in FIG. 3A;

FIG. 3C shows another embodiment of the mixer of the present invention;

FIG. 3D shows another embodiment of the mixer of the present invention;

FIG. 4A is a circuit diagram of a quadrature mixer according to an embodiment of the invention;

FIGS. 4B and 4C are respectively schematic diagrams showing waveforms of the local oscillator signals LOI/LOIB and LOQ/LOQB in the I-Quad mixer 410 and Q-Quad mixer 460 in FIG. 4A; and

FIG. 5 is a simulation diagram showing noise figure of a conventional quadrature mixer and a quadrature mixer according to an embodiment of the invention.

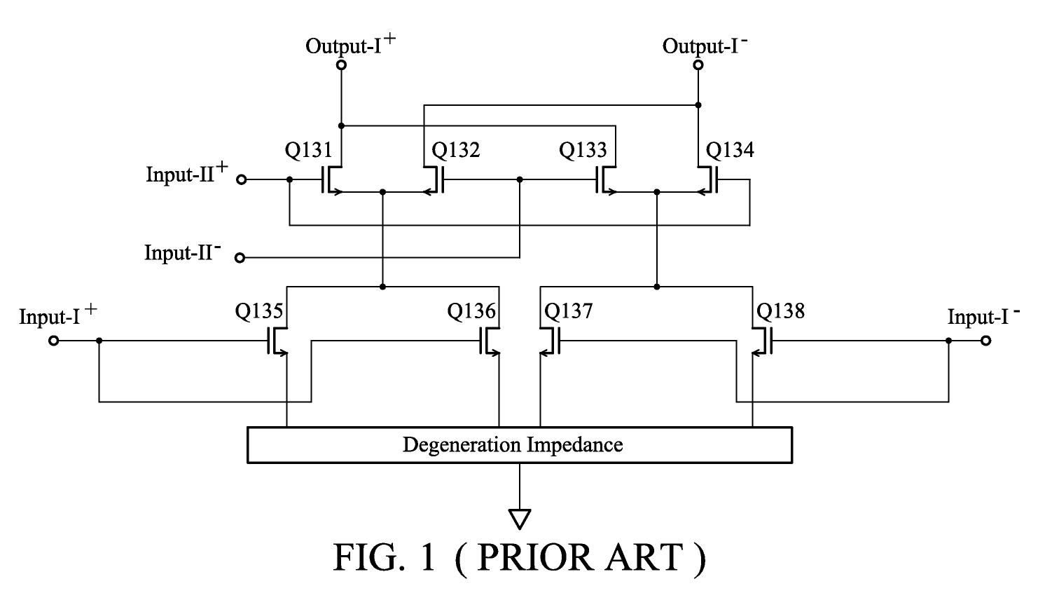

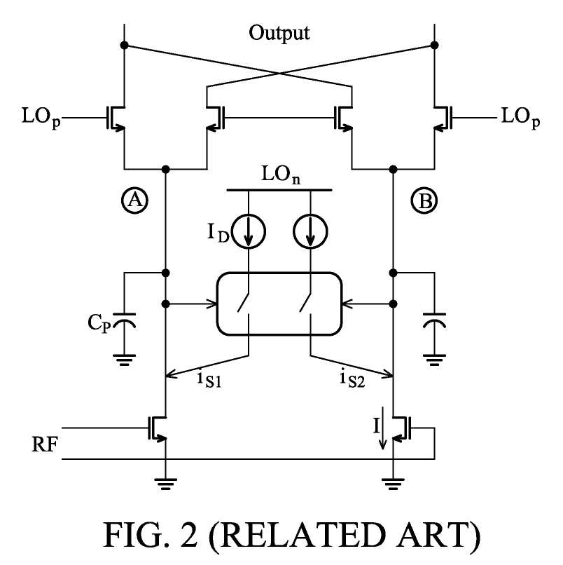

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

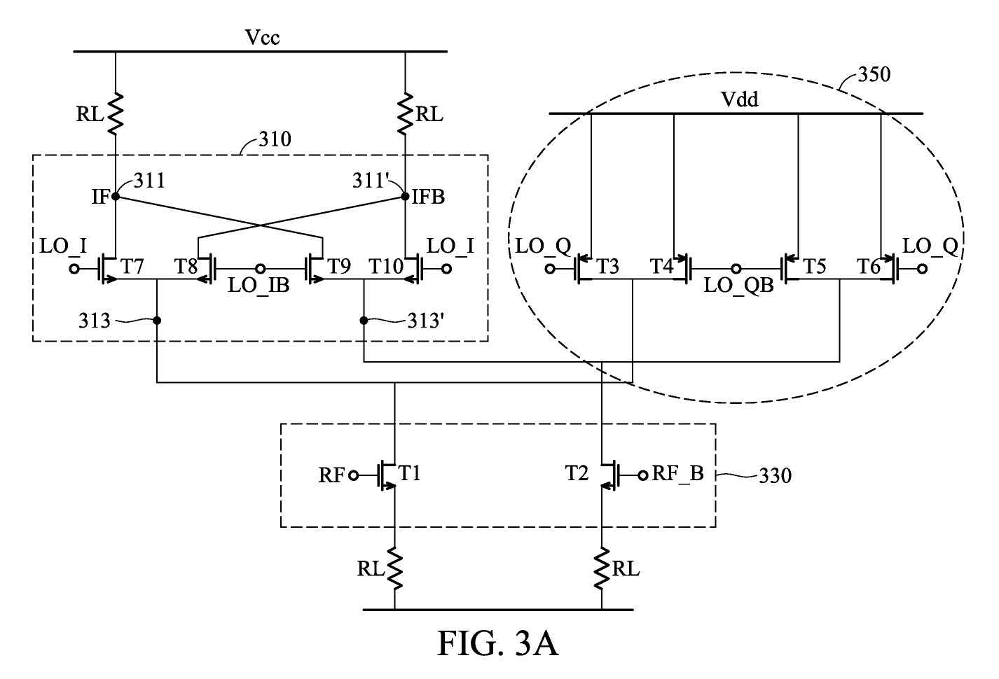

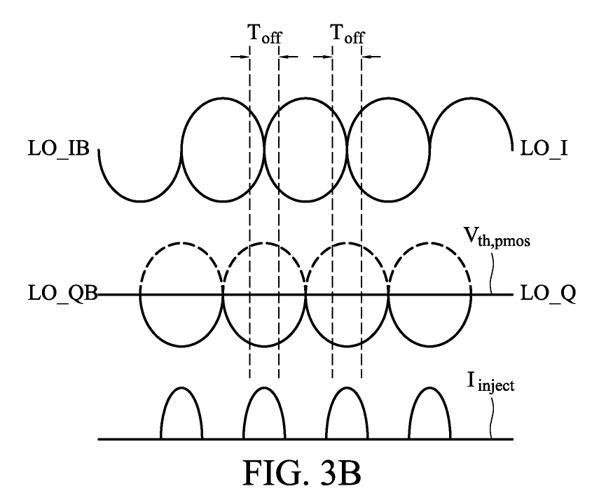

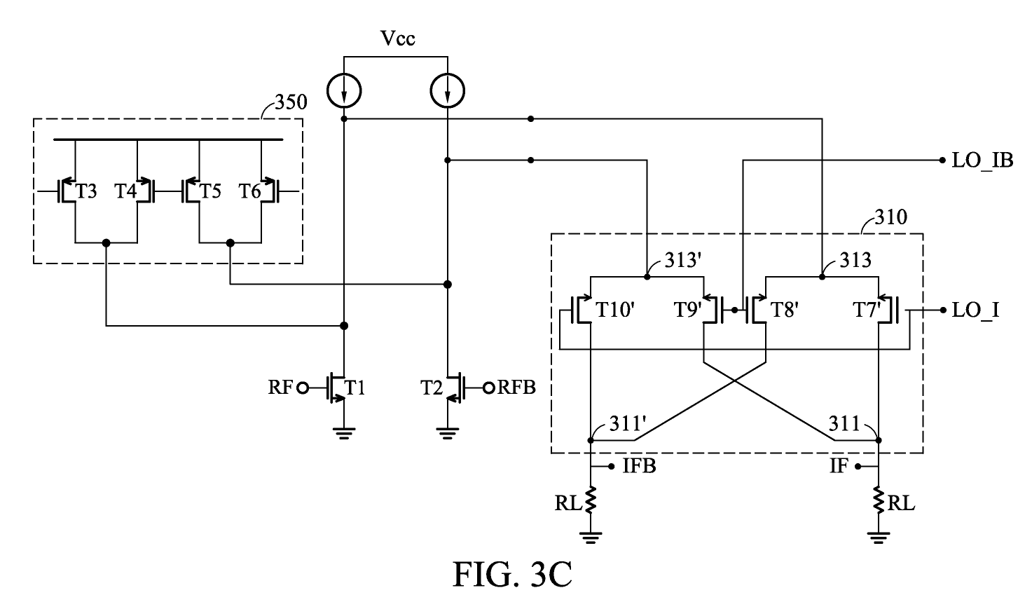

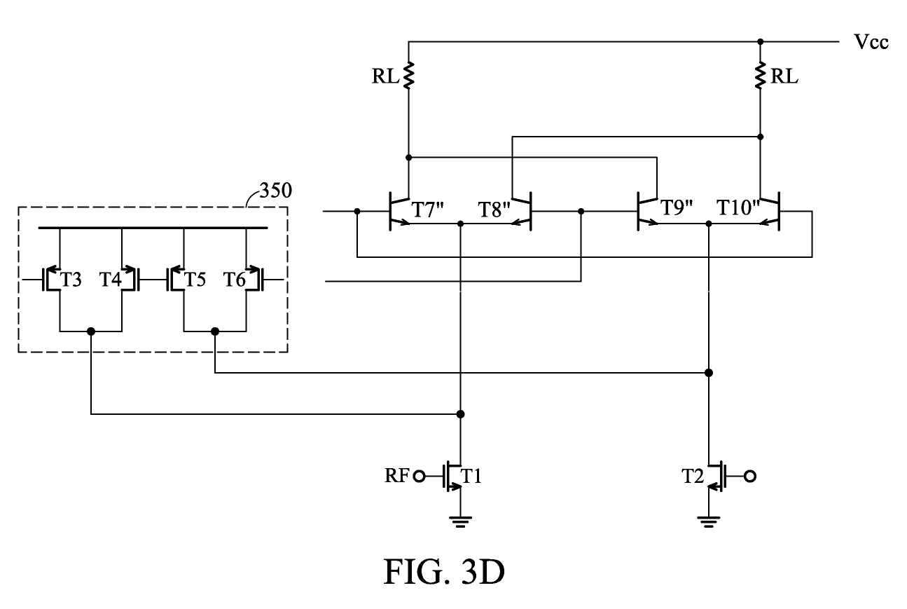

FIG. 3A is a circuit diagram of a dynamic current injection mixer according to an embodiment of the invention. The dynamic current injection mixer 300 comprises a Gilbert cell mixer core 310, a pair of load devices RL, a transconductor cell 330, and a dynamic current injection branch 350. The Gilbert cell mixer core 310 has first nodes 311 and 311′ and second nodes 313 and 313′ and comprises differential pairs of NMOS transistors T7-T8 and T9-T10 coupled therebetween. The Gilbert cell mixer core 310 receives a local oscillator signal LO_I/LO_IB, and provides an intermediate frequency (IF) signal IF/IFB at the first nodes 311 and 311′. The load devices RL are respectively coupled between the first nodes 311 and 311′ of the Gilbert cell mixer core 310 and a supply voltage Vcc. The transconductor cell 330 comprises NMOS transistors T1 and T2 coupled between the second nodes 313 and 313′ and a ground GND. Gates of the NMOS transistors T1 and T2 receive a radio frequency (RF) signal RF/RF_B. The dynamic current injection branch 350 is coupled between a fixed voltage Vdd and the second nodes 313 and 313′. Preferably, the fixed voltage Vdd is the same as the supply voltage Vcc. The dynamic current injection branch 350 comprises a first pair of PMOS transistors T3-T4 and a second pair of PMOS transistors T5-T6. PMOS transistors in each of the first pair of PMOS transistors T3-T4 and second pair of PMOS transistors T5-T6 are connected in parallel and having drains commonly coupled to a corresponding second node 313 or 313′ and gates receiving a differential input signal LO_Q and LO_QB. There is a phase difference of 90° between the local oscillator signal LO_I/LO_IB and differential input signal LO_Q and LO_QB. Preferably, the differential input signal LO_Q and LO_QB is generated from the local oscillator signal LO_I/LO_IB.

FIG. 3B is a schematic diagram showing waveforms of the local oscillator signal LO_I/LO_IB and differential input signal LO_Q and LO_QB in FIG. 3A. At zero-crossing points Toff of the local oscillator signal LO_I/LO_IB, voltage level of the differential input signal LO_Q or LO_QB is lower than threshold voltage of the PMOS transistors T3, T4, T5, and T6, allowing the PMOS transistors T3-T6 or T4-T5 to be turned on. Thus, the dynamic current injection branch 350 injects current to the transconductor cell 330. As a result, current of the NMOS transistors T7-T8 and T9-T10 is reduced. When voltage level of the differential input signal LO_Q and LO_QB exceeds the threshold voltage of the PMOS transistors T3, T4, T5, and T6 at non-zero-crossing points of the local oscillator signal LO+/LO−, the PMOS transistors T3-T6 or T4-T5 are turned off. Thus, the dynamic current injection branch 350 does not inject current to the transconductor cell 330. It is well-known that flicker noise of the Gilbert cell mixer core 310 is proportional to a current through switching transistors at zero-crossing point. Therefore, current reduction the Gilbert cell mixer core 310 at zero-crossing points of the local oscillator signal LO_I/LO_IB according to the present invention can successfully suppress the flicker noise and would be insensitive to LO noise. Preferably, amount of the dynamically injected current equals that of the transconductor cell 330, resulting in maximum current reduction of the Gilbert cell mixer core 310 at zero-crossing points of the local oscillator signal LO_I/LO_IB. It is noted that the mixer can be used for frequency up-conversion. For such a case, the radio frequency (RF) signal RF/RF_B is replaced by a base band signal.

FIG. 3C shows another embodiment of the mixer of the present invention. The main difference between the dynamic current injection mixer in FIG. 3A and in FIG. 3C is that the Gilbert cell mixer core 310 and the load devices RL are folded down and coupled to the ground GND. The NMOS transistors T7, T8, T9 and T10 in the Gilbert cell mixer core 310 are replaced by PMOS transistors.

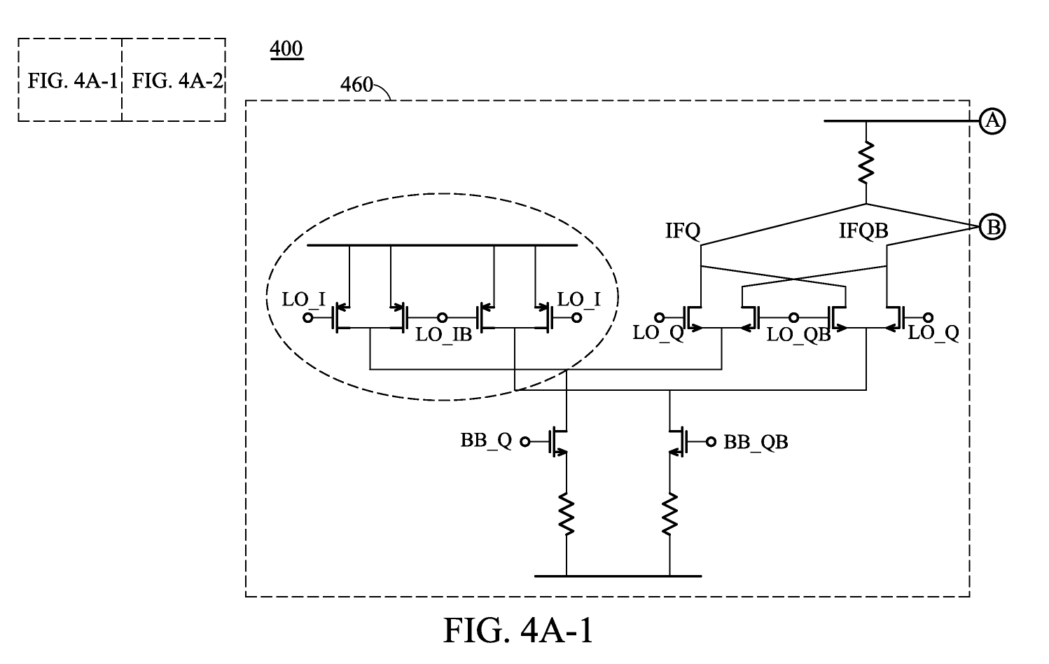

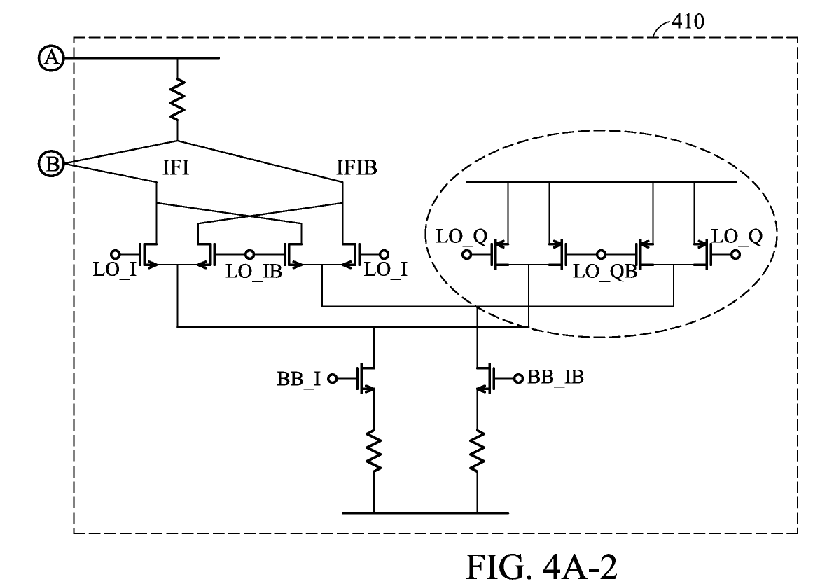

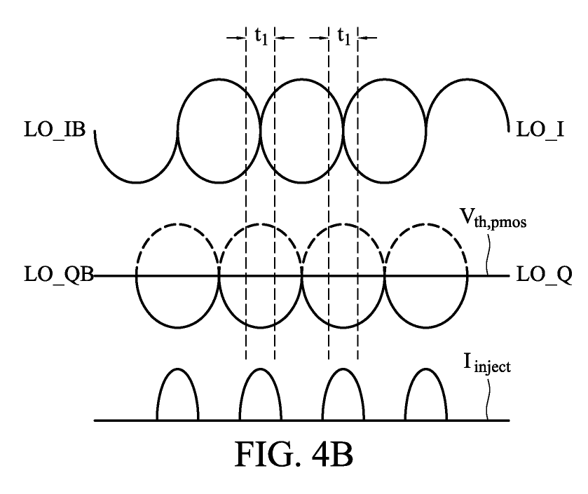

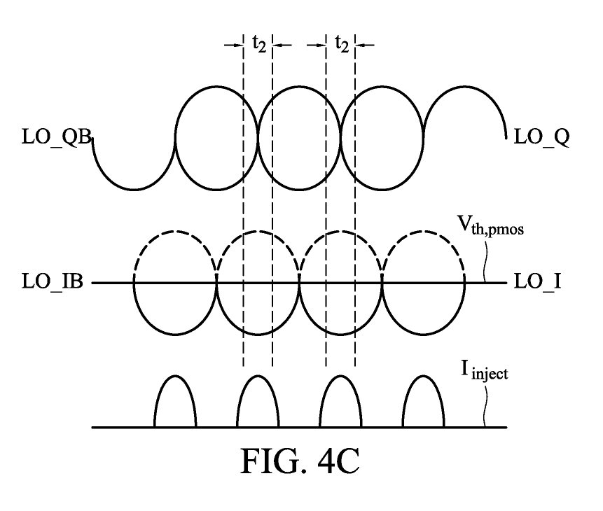

FIG. 3D shows another embodiment of the mixer of the present invention. The main difference between the dynamic current injection mixer in FIG. 3A and in FIG. 3D is that the NMOS transistors T7, T8, T9 and T10 in the Gilbert cell mixer core 310 are replaced by bipolar junction transistors (BJTs). It is noted that the Gilbert cell mixer core 310 and the load devices in FIG. 4D can also be folded down and coupled to the ground GND. In addition, the dynamic current injection cell comprising the PMOS transistors T3, T4, T5, and T6 is an embodiment and the scope is not limited thereto. Bipolar junction transistors are also applicable to the dynamic current injection branch.

FIG. 4A is a circuit diagram of a quadrature mixer according to an embodiment of the invention. In FIG. 4A, the quadrature mixer 400 comprises an I-Quad mixer 410 and a Q-Quad mixer 460. The I-Quad mixer 410 and the Q-Quad mixer 460 are both the mixers as disclosed in FIG. 3A and connected in parallel between a supply voltage Vcc and a ground GND. The Gilbert mixer core 310 in the I-Quad mixer 410 receives a local oscillator signal LO_I/LO_IB and that in the Q-Quad mixer 460 a local oscillator signal LO_Q/LO_QB. The dynamic current injection branch 350 in the I-Quad mixer 410 is controlled by a first differential signal and the Q-Quad mixer 460 controlled by a second differential signal. Preferably, the first differential signal is the same as the local oscillator signal LO_Q/LO_QB of the Q-Quad mixer 460 and the second differential the same as the local oscillator signal LO_I/LO_IB. The I-Quad mixer 410 generates an IF signal IFI/IFIB and the Q-Quad mixer 460 an IF signal IFQ/IFQB. Since the I-Quad mixer 410 and the Q-Quad mixer 460 in the quadrature mixer 400 are both the mixers as disclosed in FIG. 3A, noise figure of the quadrature mixer 400 according to an embodiment of the invention is also improved. It is noted that the disclosed variants of the dynamic current injection mixer in FIG. 3C and FIG. 3D can also be used in the quadrature mixer.

FIGS. 4B and 4C are respectively timing diagrams showing waveforms of the local oscillator signals LOI/LOIB and LOQ/LOQB and injection currents in the I-Quad mixer 410 and Q-Quad mixer 460 in FIG. 4A. In FIG. 4B, at a zero-crossing point t1 of the local oscillator signal LOI/LOIB, since voltage level of the differential signal LOQ/LOQB is lower than threshold voltage of the PMOS transistors, the dynamic current injection branch in the I-Quad mixer 410 injects current to the transconductor cell of the I-Quad mixer 410. Meanwhile, when voltage level of local oscillator signal LOI/LOIB exceeds threshold voltage of the PMOS transistors, the dynamic current injection branch in the Q-Quad mixer 460 does not inject current to the transconductor cell of the Q-Quad mixer 460, as shown in FIG. 4C. To the contrary, at a zero-crossing point t2 of the local oscillator signal LOQ/LOQB in FIG. 4C, when voltage level of the differential signal LOI/LOIB is lower than threshold voltage of the PMOS transistors, the dynamic current injection branch in the Q-Quad mixer 460 injects current to the transconductor cell of the Q-Quad mixer 460. Meanwhile, when voltage level of local oscillator signal LOQ/LOQB exceeds threshold voltage of the PMOS transistors, the dynamic current injection branch in the I-Quad mixer 410 does not inject current to the transconductor cell of the I-Quad mixer 410, as shown in FIG. 4B.

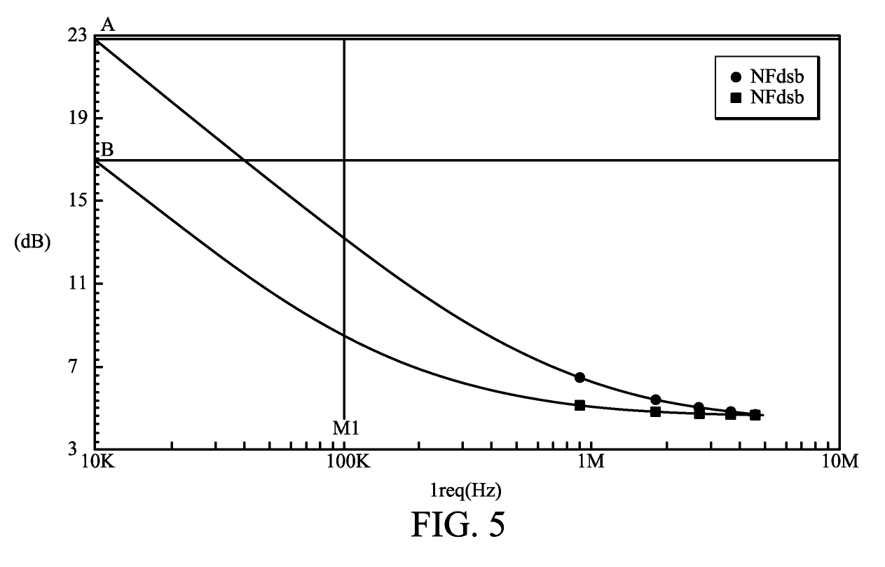

FIG. 5 is a schematic diagram showing noise figure of a conventional quadrature mixer and a quadrature mixer according to an embodiment of the invention. The dashed curve represents noise figure of the conventional quadrature mixer and the solid curve noise figure of the quadrature mixer according to an embodiment of the invention. It is shown that at a frequency of 10 KHz, noise figure of the quadrature mixer according to an embodiment of the invention is lower than that of the conventional quadrature mixer by about 6 dB.

While the invention has been described by way of example and in terms of preferred embodiment, it is to be understood that the invention is not limited thereto. Alternatively, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A mixer, comprising:
a Gilbert cell mixer core having first and second nodes, receiving a first differential input signal, and providing a differential output signal at the first nodes thereof;
a pair of load devices respectively coupled between the first nodes of the Gilbert cell mixer core and a first fixed voltage;
a transconductor cell coupled between the second nodes and a second fixed voltage and receiving a second differential input signal; and
a dynamic current injection branch coupled between a third fixed voltage and the second nodes and comprising first and second pairs of MOS transistors each connected in parallel and having drains commonly coupled to a corresponding second node and gates receiving a third differential input signal;
wherein there is a phase difference of 90° between the first and third differential input signals.

2. The mixer as claimed in claim 1, wherein the first and third fixed voltages are the same.

3. The mixer as claimed in claim 1, wherein the dynamic current injection branch injects current to the transconductor cell at zero-crossing points of the first differential input signal.

4. The mixer as claimed in claim 3, wherein amount of the injected current equals that of the transconductor cell at zero-crossing points of the first differential input signal.

5. The mixer as claimed in claim 1, wherein the first and second fixed voltages are respectively one and the other of a supply voltage and a ground.

6. The mixer as claimed in claim 1, wherein the Gilbert cell mixer core comprises differential pairs of MOS transistors.

7. The mixer as claimed in claim 1, wherein the Gilbert cell mixer core comprises differential pairs of BJTs.

8. The mixer as claimed in claim 1, wherein each of the load devices comprises a resistor.

9. The mixer as claimed in claim 1, wherein the first and second fixed voltages are the same.

10. The mixer as claimed in claim 1, wherein the third differential input signal is generated from the first differential input signal.

11. A quadrature mixer, comprising:
first and second mixers connected in parallel between first and second fixed voltages, each comprising:
a Gilbert cell mixer core having first and second nodes, receiving a first differential input signal, and providing a differential output signal at the first nodes thereof;
a pair of load devices respectively coupled between the first nodes of the Gilbert cell mixer core and a first fixed voltage;
a transconductor cell coupled between the second nodes and a second fixed voltage and receiving a second differential input signal; and
a dynamic current injection branch coupled between a third fixed voltage and the second nodes and comprising first and second pairs of MOS transistors each connected in parallel and having drains commonly coupled to a corresponding second node and gates receiving a third differential input signal;
wherein there is a phase difference of 90° between the first and third differential input signals;
wherein first differential input signals of the first and second mixers have a phase difference of 90°.

12. The quadrature mixer as claimed in claim 11, wherein the first and third fixed voltages are the same.

13. The quadrature mixer as claimed in claim 11, wherein the dynamic current injection branches inject current to the transconductor cell at zero-crossing points of the first differential input signal in each of the first and second mixers.

14. The mixer as claimed in claim 13, wherein amount of the injected current equals that of the transconductor cell at zero-crossing points of the first differential input signal in each of the first and second mixers.

15. The quadrature quadrature mixer as claimed in claim 11, wherein the first and second fixed voltages are respectively one and the other of a supply voltage and a ground.

16. The quadrature mixer as claimed in claim 11, wherein the Gilbert cell mixer core comprises differential pairs of MOS transistors.

17. The quadrature mixer as claimed in claim 11, wherein the Gilbert cell mixer core comprises differential pairs of BJTs.

18. The quadrature mixer as claimed in claim 11, wherein each of the load devices comprises a resistor.

19. The quadrature mixer as claimed in claim 11, wherein the first and second fixed voltages are the same.

20. The quadrature mixer as claimed in claim 11, wherein the third differential input signal is generated from the first differential input signal.

21. The quadrature mixer as claimed in claim 11, wherein the third differential input signal of one of the first and second mixers is the same as the first differential input signal of the other of the first and second mixers.
